(19) United States
(12) Patent Application Publication
(10) Pub. No.: US 2026/0343821 A1
(43) Pub. Date: Oct. 29, 2026

(54) THERMAL CONDUCTIVE STRUCTURE, ELECTRONIC PACKAGE, AND MANUFACTURING METHOD THEREOF

(71) Applicant: SILICONWARE PRECISION INDUSTRIES CO., LTD., Taichung City (TW)

(72) Inventors: Chuan-Shun LI, Taichung City (TW); Wen-Yu TENG, Taichung City (TW); Liang-Yi HUNG, Taichung City (TW)

(73) Assignee: SILICONWARE PRECISION INDUSTRIES CO., LTD., Taichung City (TW)

(21) Appl. No.: 19/409,103

(22) Filed: Dec. 4, 2025

(30) Foreign Application Priority Data
Apr. 25, 2025 (TW) 114115748

(51) Int. Cl. H05K 7/20

(52) U.S. Cl. CPC H05K 7/2039

(57) ABSTRACT

An electronic package and its thermal conductive structure and a manufacturing method thereof are provided. The electronic package includes a carrier, an electronic component arranged on the carrier, and a heat dissipation member bonded to the electronic component via a thermal conductive structure. The thermal conductive structure includes a middle layer and a nano layer formed on at least one side of the middle layer, so that the middle layer provides high thermal conductivity and high compressibility, and the nano layer provides a coefficient of high thermal conductivity, thereby improving the heat dissipation effect of the electronic package.

### BACKGROUND

### 1. Technical Field

The present disclosure relates to a semiconductor device, and more particularly, to an electronic package with its thermal conductive structure and a manufacturing method thereof.

### 2. Description of Related Art

As the demand for electronic products in terms of functionality and processing speed increases, semiconductor chips, being the core components of these electronic products, must have higher density electronic circuits and electronic components, thus semiconductor chips generate more heat energy during operation. Furthermore, the conventional encapsulant for encapsulating the semiconductor chips is a poor heat transfer material, with a coefficient of thermal conductivity of only 0.8 W/m·k, leading to poor heat dissipation efficiency. If the heat generated by the semiconductor chip is not dissipated effectively, it may cause damage to the semiconductor chip and affect product reliability.

Therefore, to rapidly dissipate the heat to the external environment, the industry usually arranges a heat sink in the semiconductor package. The heat sink is usually bonded to the back of the semiconductor chip using a heat dissipation material, such as a thermal interface material (TIM), to dissipate the heat generated by the semiconductor chip through the heat dissipation material and the heat sink. In addition, the top surface of the heat sink is usually exposed from the encapsulant or directly exposed to the atmosphere to improve heat dissipation.

FIG. 1 is a schematic cross-sectional view showing a conventional semiconductor package 1. In the conventional semiconductor package 1, a semiconductor chip 12 is disposed on a package substrate 11 using flip-chip bonding, then a heat sink 13 is bonded on the back of the semiconductor chip 12 through a thermal interface material (TIM) 14. Generally, when the thermal interface material 14 with a low melting point (such as an indium metal sheet) is disposed on the back of the semiconductor chip 12, a back side metal (BSM) 15 must be applied on the back of the semiconductor chip 12, and the back side metal 15 may be composed of multiple layers of metal. However, after the thermal interface material 14 with a low melting point is set, the low melting point thermal interface material 14 tends to slide or overflow from the back edge of the semiconductor chip 12 due to the machine operation before entering the high temperature process. This causes insufficient coverage of the thermal interface material 14 between the heat sink 13 and the semiconductor chip 12, which reduces the heat dissipation capacity of the semiconductor package, resulting in poor heat dissipation effect or even damage to the electronic products.

To this end, the conventional solution in the industry is to adhere the back side metal to the thermal interface material using polymer glue. However, the polymer glue hinders the reaction of metal ions when the thermal interface material with a low melting point is connected to the back side metal, resulting in voids and cracks in the welding interface, which decrease the heat dissipation efficiency.

Therefore, there is an urgent issue to overcome the aforementioned problems of conventional techniques.

### SUMMARY

In view of the aforementioned shortcomings of the prior art, the present disclosure provides a thermal conductive structure which is disposed between an electronic component and a heat dissipation member, the thermal conductive structure including: a middle layer; and a nano layer formed on at least one side of the middle layer.

The present disclosure further provides an electronic package, the electronic package including: a carrier; an electronic component disposed on the carrier; a thermal conductive structure including a middle layer and a nano layer formed on at least one side of the middle layer; and a heat dissipation member bonded to the electronic component via the thermal conductive structure.

The present disclosure further provides a method of manufacturing an electronic package, the method including: providing a carrier and disposing an electronic component on the carrier; providing a heat dissipation member and a thermal conductive structure, wherein the thermal conductive structure includes a middle layer and a nano layer formed on at least one side of the middle layer; and bonding the heat dissipation member to the electronic component via the thermal conductive structure.

In the aforementioned electronic package and its thermal conductive structure and the method thereof, the middle layer is a graphite sheet. The nano layer is a nanoporous metal layer. The nanoporous metal layer is nanoporous copper (Cu). Opposite sides of the middle layer are formed with the nano layer.

In the aforementioned electronic package and its thermal conductive structure and the method thereof, a metal layer is further formed between the middle layer and the nano layer. The metal layer is gold or silver.

In the aforementioned electronic package and its thermal conductive structure and the method thereof, the electronic component has an active surface and a non-active surface opposite to the active surface, and the active surface of the electronic component is attached to the carrier and electrically connected to the carrier. A back side metal is formed on the non-active surface of the electronic component.

In the aforementioned thermal electronic package and its conductive structure and the method thereof, the heat dissipation member includes a body and a support portion extending outward from a surface of the body, and the support portion of the heat dissipation member is attached to the carrier via an adhesive layer.

In the aforementioned electronic package and its thermal conductive structure and the method thereof, the heat dissipation member is bonded to the electronic component through thermal compression bonding technology.

The present disclosure is mainly implemented to provide a thermal conductive structure including a middle layer and a nano layer formed on at least one side of the middle layer, wherein the middle layer is a graphite sheet, and the nano layer is a nanoporous metal layer (e.g., nanoporous Cu). Due to its high thermal conductivity and high compressibility, the graphite can effectively fill and smooth out the surface roughness between the electronic component and the heat dissipation member. Additionally, the compressed graphite sheet can reduce thermal impedance. In addition, nanoporous Cu has a coefficient of thermal conductivity of up to 340 W/m·k, and its loose structure can meet the conditions for thermal compression bonding. Furthermore, both the graphite sheet and nanoporous Cu are highly flexible and resistant to external forces or thermal stress deformation, preventing cracking or delamination. This avoids the use of polymer adhesives, which can reduce heat dissipation efficiency.

### BRIEF DESCRIPTION OF THE DRAWINGS

FIG. 1 is a schematic cross-sectional view showing a conventional semiconductor package.

FIG. 2A to FIG. 2D are schematic cross-sectional views showing a method of manufacturing an electronic package and its thermal conductive structure according to the present disclosure.

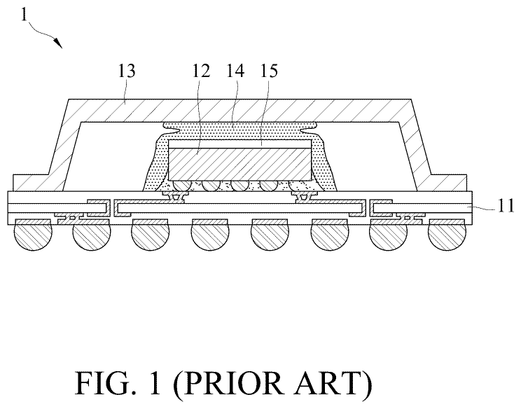

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like are merely used for clear explanation rather than limiting the practicable scope of the present disclosure, and thus, alterations or adjustments of the relative relationships thereof without essentially altering the technical contents should still be considered in the practicable scope of the present disclosure.

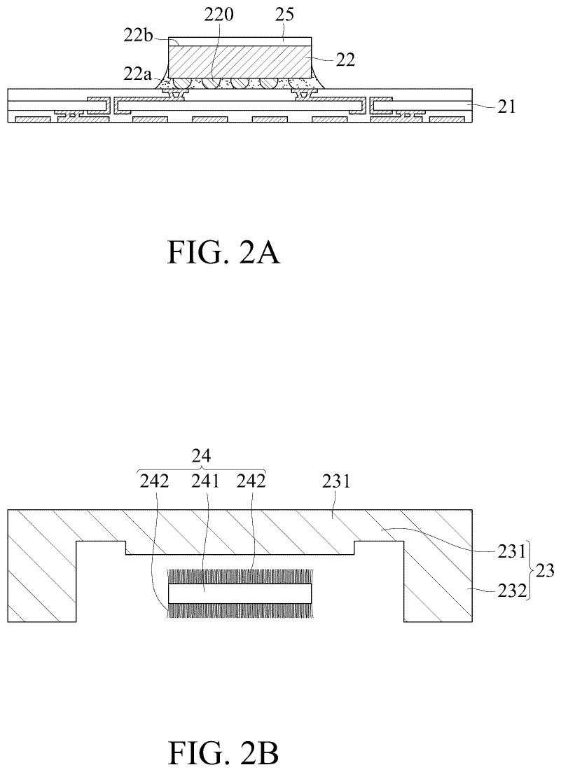

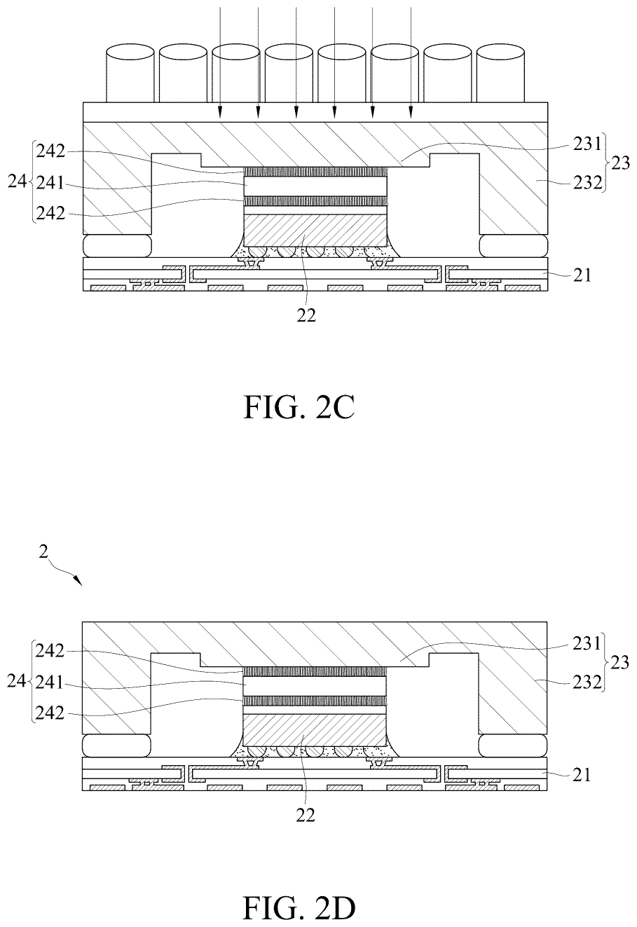

FIG. 2A to FIG. 2D are schematic cross-sectional views showing a method of manufacturing an electronic package and its thermal conductive structure of the present disclosure.

As shown in FIG. 2A, a carrier 21 is provided, and an electronic component 22 is attached to the carrier 21.

The carrier 21 is, for example, a package substrate with a core layer and a circuit structure, or a coreless circuit structure, which includes a dielectric layer and circuit layer (e.g., a redistribution layer). Furthermore, the carrier 21 can also be a lead frame, a silicon interposer, a wafer, or other board with metal routing, etc., and is not limited to the above.

The electronic component 22 is attached to the carrier 21 and electrically connected to the circuit layer. The electronic component 22 can be an active component, a passive component, a package structure, or a combination thereof. The active component can be a semiconductor chip, and the passive component is, for example, a resistor, a capacitor, and an inductor, etc. In one embodiment, the electronic component 22 is a semiconductor chip and has an active surface 22a and a non-active surface 22b opposite to the active surface 22a, and the electronic component 22 is mounted onto the carrier 21 in a flip-chip manner, with the active surface 22a electrically connected to the carrier 21 via a plurality of conductive bumps 220.

Furthermore, a back side metal 25 is disposed on the non-active surface 22b of the electronic component 22 to facilitate the subsequent combination of the electronic component 22 and the heat dissipation member. The back side metal 25 may be a multi-layer metal layer structure, such as one of the group consisting of aluminum (Al), titanium (Ti), nickel (Ni), vanadium (V) and gold (Au).

As shown in FIG. 2B, a heat dissipation member 23 and a thermal conductive structure 24 are provided.

The heat dissipation member (23 includes a body 231 and support portions 232 extending outward from the surface of the body 231. The dissipation member 23 is, for example, made of copper metal.

The thermal conductive structure 24 is, for example, a thermal interface material (TIM) structure, which includes a middle layer 241 and a nano layer 242 formed on at least one side of the middle layer 241. In one embodiment, nano layers 242 are formed on opposite two sides of the middle layer 241. In one embodiment, the middle layer 241 is a graphite sheet. Due to its high thermal conductivity and high compressibility, the graphite sheet can effectively fill and smooth out the surface roughness between a heat source (i.e., the electronic component 22) and the heat dissipation member 23. Additionally, the compressed graphite sheet reduces thermal impedance, making it an effective thermal conductive interface material. In one embodiment, the nano layer 242 is a nanoporous metal layer (such as nanoporous Copper (NP-Cu)), which can be formed by coating metal layers (such as gold or silver) on both sides of the graphite sheet as a coating layer to increase electrical conductivity, followed by the growth of the nanoporous Cu on the graphite sheet via electroplating. The nanoporous metal layer is not a solid structure, but has multiple voids and a coefficient of thermal conductivity of up to 340 W/m·K (such as nanoporous Cu), effectively dissipating heat.

As shown in FIG. 2C, the heat dissipation member 23 covers the electronic component 22 and is bonded to the electronic component 22 via the thermal conductive structure 24.

In one embodiment, the heat dissipation member 23 is bonded to the electronic component 22 via thermal compression bonding (TCB) at a temperature of 150-250 °C and a pressure of 10-20 MPa, with the thermal conductive structure 24 positioned between the heat dissipation member 23 and the electronic component 22.

As shown in FIG. 2D, one side of the thermal conductive structure 24 is bonded to the heat dissipation member 23, and the other side is bonded to the electronic component 22 (back side metal 25) through thermal compression bonding technology. At the same time, the support portions 232 of the heat dissipation member 23 are attached to the carrier 21 via an adhesive layer, such that the heat dissipation member 23 is vertically disposed on the carrier 21 and interfaces with the electronic component 22 via the thermal conductive structure 24, thereby forming the electronic package 2 of the present disclosure.

The present disclosure further discloses an electronic package 2, including: a carrier 21; an electronic component 22 with an active surface 22a and a non-active surface 22b opposite to the active surface 22a, wherein the electronic component 22 is attached to the carrier 21 with the active surface 22a and is electrically connected to the carrier 21; a back side metal 25 formed on the non-active surface 22b; a thermal conductive structure 24 including a middle layer 241 and a nano layer 242 formed on at least one side of the middle layer 241; a heat dissipation member 23 bonded to the electronic component 22 via the thermal conductive structure 24.

The thermal conductive structure 24 is a thermal interface material (TIM) structure, the middle layer 241 is a graphite sheet, and the nano layer 242 is a nanoporous metal layer (nanoporous Cu).

The heat dissipation member 23 includes a body 231 and support portions 232 extending outward from the surface of the body 231, such that one side of the thermal conductive structure 24 is bonded to the body 231 of the heat dissipation member 23, and the other side is bonded to the electronic component 22 (back side metal 25). At the same time, the support portions 232 of the heat dissipation member 23 are attached to the carrier 21 via an adhesive layer, such that the heat dissipation member 23 is vertically disposed on the carrier 21 and interfaces with the electronic component 22 via the thermal conductive structure 24.

To sum up, the electronic package and its thermal conductive structure and the method thereof of the present disclosure mainly provide a thermal conductive structure including a middle layer and a nano layer formed on at least one side of the middle layer, wherein the middle layer is a graphite sheet, and the nano layer is a nanoporous metal layer (e.g., nanoporous Cu). Due to its high thermal conductivity and high compressibility, the graphite sheet can effectively fill and smooth out the surface roughness between the electronic component and the heat dissipation member. Additionally, the compressed graphite sheet can reduce thermal impedance.

In addition, nanoporous Cu has a coefficient of thermal conductivity of up to 340 W/m·k, and its loose structure can meet the conditions for thermal compression bonding. Furthermore, both the graphite sheet and nanoporous Cu are highly flexible and resistant to external forces or thermal stress deformation, preventing cracking or delamination. This avoids the use of polymer adhesives, which can reduce heat dissipation efficiency. In addition, the aforementioned structure does not require the development of new processes and materials or the purchase of machines, and the existing technical problems in the industry can be solved using existing materials, processes and machines, thereby avoiding be a lot of addition costs.

The above embodiments are disposed for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A thermal conductive structure configured to be disposed between an electronic component and a heat dissipation member, the thermal conductive structure comprising:
a middle layer; and
a nano layer formed on at least one side of the middle layer.

2. The thermal conductive structure of claim 1, wherein the middle layer is a graphite sheet.

3. The thermal conductive structure of claim 1, wherein the nano layer is a nanoporous metal layer.

4. The thermal conductive structure of claim 3, wherein the nanoporous metal layer is nanoporous Copper (Cu).

5. The thermal conductive structure of claim 1, wherein opposite sides of the middle layer are formed with the nano layer.

6. The thermal conductive structure of claim 1, further comprising a metal layer formed between the middle layer and the nano layer.

7. The thermal conductive structure of claim 6, wherein the metal layer is gold or silver.

8. An electronic package, comprising:
a carrier;
an electronic component disposed on the carrier;
a thermal conductive structure comprising a middle layer and a nano layer formed on at least one side of the middle layer; and
a heat dissipation member bonded to the electronic component via the thermal conductive structure.

9. The electronic package of claim 8, wherein the middle layer is a graphite sheet.

10. The electronic package of claim 8, wherein the nano layer is a nanoporous metal layer.

11. The electronic package of claim 10, wherein the nanoporous metal layer is nanoporous Cu.

12. The electronic package of claim 8, wherein opposite sides of the middle layer are formed with the nano layer.

13. The electronic package of claim 8, wherein the thermal conductive structure further comprises a metal layer formed between the middle layer and the nano layer.

14. The electronic package of claim 13, wherein the metal layer is gold or silver.

15. The electronic package of claim 8, wherein the electronic component has an active surface and a non-active surface opposite to the active surface, and the active surface of the electronic component is attached to the carrier and electrically connected to the carrier.

16. The electronic package of claim 15, further comprising a back side metal formed on the non-active surface of the electronic component.

17. The electronic package of claim 8, wherein the heat dissipation member comprises a body and a support portion extending outward from a surface of the body, and the support portion of the heat dissipation member is attached to the carrier via an adhesive layer.

18. A method of manufacturing an electronic package, the method comprising:
disposing an electronic component on a carrier; and
bonding a heat dissipation member on the electronic component via a thermal conductive structure, wherein the thermal conductive structure comprises a middle layer and a nano layer formed on at least one side of the middle layer.

19. The method of claim 18, wherein the middle layer is a graphite sheet.

20. The method of claim 18, wherein the nano layer is a nanoporous metal layer.

21. The method of claim 20, wherein the nanoporous metal layer is nanoporous Cu.

22. The method of claim 18, wherein opposite sides of the middle layer are formed with the nano layer.

23. The method of claim 18, wherein the thermal conductive structure further comprises a metal layer formed between the middle layer and the nano layer.

24. The method of claim 23, wherein the metal layer is gold or silver.

25. The method of claim 18, wherein the electronic component has an active surface and a non-active surface opposite to the active surface, and the active surface of the electronic component is placed on the carrier and electrically connected to the carrier.

26. The method of claim 25, further comprising forming a back side metal on the non-active surface of the electronic component.

27. The method of claim 18, wherein the heat dissipation member comprises a body and a support portion extending outward from a surface of the body, and the support portion of the heat dissipation member is attached to the carrier via an adhesive layer.

28. The method of claim 18, wherein the heat dissipation member is bonded to the electronic component through thermal compression bonding technology.
